(19) United States
(12) Patent Application Publication
(10) Pub. No.: US 2012/0267153 A1
(43) Pub. Date: Oct. 25, 2012

(54) COUPLING DEVICE, ASSEMBLY HAVING A COUPLING DEVICE, AND METHOD FOR PRODUCING AN ASSEMBLY HAVING A COUPLING DEVICE

(75) Inventor: Christian Solf, Karlsruhe (DE)

(73) Assignee: ROBERT BOSCH GMBH, Stuttgart (DE)

(21) Appl. No.: 13/503,581

(22) PCT Filed: Oct. 5, 2010
(86) PCT No.: PCT/EP10/64806

§ 371 Date: Jul. 9, 2012

(30) Foreign Application Priority Data
Oct. 22, 2009 (DE) 10 2009 045 911.1

(51) Int. Cl. H05K 1/18; H05K 3/30; H05K 1/11

(52) U.S. Cl. 174/260; 174/261; 29/841

(57) ABSTRACT

The invention relates to a method for a coupling device (1) for connecting an electrical/electronic component (16), in particular a sensor (17), having a substrate, in particular a circuit board, wherein the coupling device (1) comprises at least one electrical connection (25) for electrical contacting and at least one damper element (12) for movement uncoupling, wherein the electrical connection is formed by a lead frame (3) and the lead frame (3) is overmolded in regions by a damping mass (11) as a damper element (12). The invention furthermore relates to an assembly having a coupling device and a method for producing said type of assembly.

### BACKGROUND OF THE INVENTION

The invention relates to a coupling device for connecting an electrical/electronic structural part, in particular a sensor, having a substrate, in particular a circuit board, wherein the coupling device comprises at least one electrical connection for the making of electrical contact and at least one damper element for the decoupling of movement.

Furthermore, the invention relates to an assembly having at least one electrical/electronic structural part, in particular a sensor, which can be arranged on a substrate, in particular a circuit board, and having a coupling device for connecting the structural part to the substrate, wherein the coupling device comprises at least one electrical connection for the making of electrical contact and at least one damper element for the decoupling of movement.

Finally, the invention relates to a method for producing an assembly, in particular such as that described above, wherein the assembly comprises at least one electrical/electronic structural part, in particular a sensor, which can be arranged on a substrate, in particular a circuit board, and a coupling device for connecting the structural part to the substrate, wherein the coupling device comprises at least one electrical connection for the making of electrical contact and at least one damper element for the decoupling of movement.

Coupling devices of the type mentioned at the beginning and a corresponding assembly with a coupling device and a method for producing the latter are known from the prior art. Thus it is known in the case of vibration-sensitive structural parts, such as for example in the case of sensors and in particular in the case of micromechanical sensors, to attach them to a substrate by means of a movement-decoupling coupling device. Within the scope of this application, the decoupling of movement should be understood as meaning mechanical decoupling, which serves primarily for decoupling vibrations occurring (vibration decoupling), but may also serve for compensating for tolerances, in particular for compensating for stresses occurring during operation. Thus, for example, there is often the problem that stresses occur between the structural part and the substrate, caused for example by different coefficients of thermal expansion, so that the structural part and the substrate expand/move differently when heated and, as a result, they become stressed with respect to each other at their points of attachment. In the worst case, this may lead to the rupturing of connecting points and consequently to the failure of the structural part.

DE 10 2006 002 350 A1 discloses an inertial sensor assembly in which a sensor module is arranged on a carrier substrate with an elastically deformable coupling element interposed, wherein the material of the damper is injected into a gap present between the sensor module and the carrier substrate in the manner of a frame around the sensor module. The sensor module is then connected by means of bonding wires to a circuit arranged on the carrier substrate. It is therefore known that the coupling device is formed as two parts.

### SUMMARY OF THE INVENTION

According to the invention, it is provided that the electrical connection is formed by a punched mesh and the punched mesh is encapsulated at least in certain regions by a damping mass as a damper element. It is therefore provided that the electrical connection of the coupling device between the substrate and the structural part is formed by a punched mesh. Punched meshes are generally known to a person skilled in the art and allow a stable electrical connection in a simple manner. According to the invention, the punched mesh is encapsulated at least in certain regions by a damping mass in such a way that the damper element is formed. As a result, the punched mesh and the damper element form a unit or a compact, almost one-part coupling device. The encapsulation of the punched mesh with the damping mass has the effect on the one hand that the punched mesh is given greater stability and on the other hand that a damping effect is provided. The fact that the punched mesh itself has a damping effect as a result of the damping mass surrounding it and the fact that the damping mass itself, which is formed as a damping element, is therefore preferably itself in direct contact with the substrate and the structural part, at least in certain regions, means that a decoupling of movement is brought about between the substrate and the structural part.

Advantageously, the punched mesh forms at least in certain regions at least one spring element. Advantageously, the punched mesh has at least in certain regions a three-dimensional structure for this purpose. Thus, the spring element may, for example, be formed by a web running obliquely in relation to the rest of the punched mesh or by a bent-around spring tongue that is free at one end. Being formed in this advantageous way provides a spring-mass system with damping which can be arranged between the substrate and the structural part.

Expediently, the punched mesh has contact plates that are exposed at least on one side. At least the contact plates are therefore not encapsulated on all sides by the damping mass. Rather, the contact areas rest on the damping element or on the damping mass, wherein one side, namely the side having a contact area, is freely accessible.

Advantageously, the damping mass is silicone or another material having similar properties.

The assembly according to the invention is distinguished by a coupling device such as that described above. It is consequently provided that the assembly comprises a coupling device by means of which the structural part can be arranged on the substrate. This provides a particularly favorable decoupling of movement, which permanently ensures the functional capability of the assembly.

According to an advantageous development, it is provided that the structural part has a housing, in particular an LGA housing (Land Grid Area housing) with at least one electrical contact, which rests on the contact plate or on the contact area of the punched mesh. The resting of the electrical contact on the contact area of the punched mesh establishes the electrical connection between the structural part and the substrate.

The contact is preferably soldered to the contact area. As a result, the structural part is soldered and fixedly connected to the coupling element. The coupling device can expediently also be connected correspondingly to the substrate, in particular to the circuit board, preferably by soldering. On account of the advantageous coupling device, vibrations and/or stresses occurring are compensated or eliminated, whereby the forces acting on the soldered connection(s) do not cause the soldered connection to be destroyed.

Furthermore, it is provided that at least one electrical/electronic component of the structural part is arranged on the damper element. In this case, the coupling device is consequently no longer provided as an independent structural element of the assembly but rather as an integrated/integral element. The damper element of the coupling device serves here as a carrier for a component of the structural part and consequently forms a constituent part of the structural part. The direct arrangement of the component on the damper element provides a particularly compact assembly.

Expediently, the component is electrically connected or operatively connected to the contact area/the contact plate of the punched mesh by means of at least one bonded connection. Consequently, it is no longer intended that the electrical contact with the structural part should be made by way of a housing of the structural part but instead it can be made with respect to the punched mesh directly by the corresponding component of the structural part. A number of contact plates are expediently provided.

Finally, it is provided that the coupling device is integrated at least in certain regions with the component and the contact plate in a molded housing. In other words, in this case the housing of the structural part is applied directly to the coupling device or to the damping element and/or the component, for example by encapsulation and/or overmolding. This makes it possible to create a particularly compact and easy-to-handle unit which is immune to vibrations and/or temperature-induced stresses.

The method according to the invention is distinguished by the fact that the electrical connection is formed by a punched mesh, and the punched mesh is encapsulated at least in certain regions with a damping mass to form the damper element. To do so, first the punched mesh is punched out from a base material by a punching operation and at the same time or subsequently brought into the desired shape by a stamping and/or bending operation. Subsequently, the punched mesh is arranged in a mold which forms the negative of the damper element to be created. In the mold, the damping mass is injected at least in certain regions around the punched mesh. The mold thereby gives the damper element its later contour.

According to an advantageous development, it is provided that a housing of the structural part is soldered to the punched mesh. Corresponding electrical contacts provided on the housing are of course thereby soldered to the punched mesh, and in particular to exposed contact plates of the punched mesh. As a result, on the one hand the electrical contact between the structural part and the punched mesh is realized, and on the other hand the housing, and consequently also the structural part, is attached to the punched mesh or to the coupling device. Correspondingly, the punched mesh is soldered at a different point to the substrate, expediently to corresponding mating contacts of the substrate, thereby establishing a connection between the structural part and the substrate that can withstand loading.

Advantageously, at least one electrical/electronic component of the structural part is arranged on the damper element and is electrically connected to the punched mesh. For the connection, preferably bonded connections are established. It is expedient in this case to dispense with an electrical connection between the housing and the punched mesh, since then the component is (already) electrically connected directly to the punched mesh.

To protect the component and the bonded connections and to complete the structural part, preferably a housing is finally produced by a molding operation, so that at least the component and the bonded connections, and expediently also a further region of the damper element or of the coupling device, are housed. Preferably, the side of the coupling device having the component is completely covered by the molded housing.

Altogether, a particularly favorable and easy-to-produce mechanical decoupling of movement or decoupling of vibration and stress is ensured in this way between the structural part and the substrate, wherein the coupling device preferably forms an integral constituent part of the structural part or is produced as such.

### BRIEF DESCRIPTION OF THE DRAWINGS

The invention is to be explained in more detail below on the basis of exemplary embodiments. In the figures:

FIGS. 1A to 1D show steps for producing an advantageous coupling device,

FIGS. 2A and 2B show the coupling device with an electrical/electronic structural part in different views,

FIG. 3 shows an alternative embodiment of the coupling device,

FIG. 4 shows the coupling device as an integral constituent part of the structural part and

FIG. 5 shows the structural part with the advantageous coupling device in a perspective representation.

### DETAILED DESCRIPTION

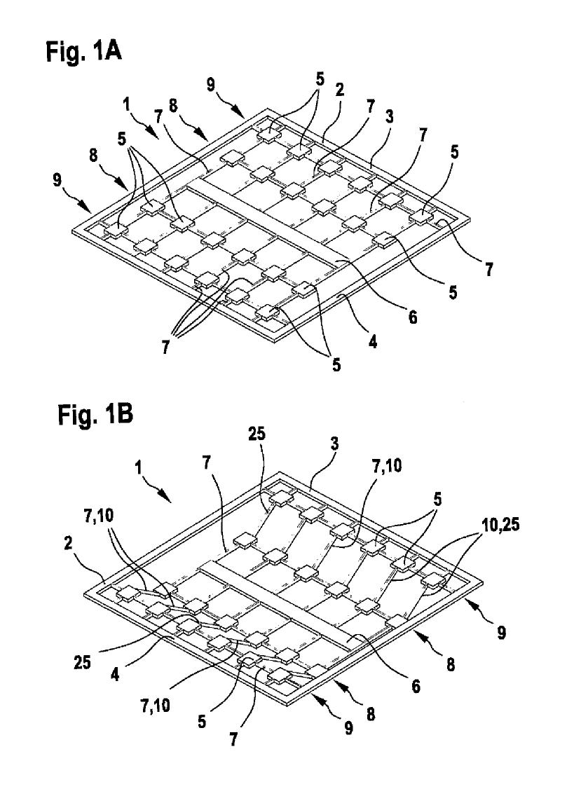

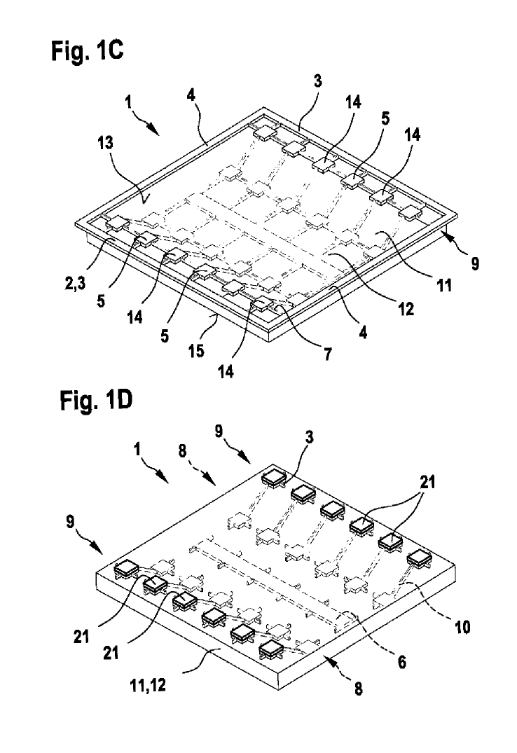

FIGS. 1A to 1D show different steps for producing an advantageous coupling device 1. Firstly, a punched mesh 3 is produced from a copper sheet 2 by punching out. In the present exemplary embodiment, the punched mesh 3 has a substantially square frame 4, within which a multiplicity of square-shaped contact plates 5 and a web 6 extending over almost the entire width of the punched mesh 3 are arranged and are connected to the frame 4 by means of connecting webs 7. The web 6 is centrally arranged, while the contact plates 5 are arranged on both sides of the web 6, respectively running in two rows parallel to the web, wherein the row of contact plates 5 respectively lying closer to the web is generally denoted hereafter by 8 and the row of contact plates 5 respectively lying further to the outside is generally denoted hereafter by 9.

In a second step, according to FIG. 1B, the punched mesh 3 is re-shaped by a bending process in such a way that the outer-lying rows 9 of the contact plates 5 lie in a plane at a distance from the inner-lying rows 8 and the web 6. In other words, in the present exemplary embodiment the punched mesh 1 is given a substantially U-shaped cross section. It is of course also conceivable in this respect to carry out the punching operation and the bending operation simultaneously or substantially simultaneously in one punching-bending step. The U shape of the punched mesh 3 expediently does not have members that are perpendicular to one another, but members that run at an angle, which run from the connecting webs 7 between the row 9 of outer-lying contact plates and the row 8 of inner-lying contact plates 5. This angled form gives the punched mesh 3 resilient properties, wherein said connecting webs 7 between the rows 8 and 9 respectively form spring elements 10 of the punched mesh 3.

In a step which then follows, the punched mesh 3 is encapsulated in certain regions by a damping mass 11 in such a way that the damping mass 11 forms a damper element 12. In particular, the spring elements 10 are encapsulated at least substantially completely. The damper element 12 likewise has a square contour. The contact plates 5 of the outer-lying rows 9 thereby rest on an upper side 13 of the damper element 12, so that their respective side that is facing away from the damper element and is exposed forms a contact area 14. There is a corresponding situation on the underside 15 of the damper element 12, on which the web 6 and the contact plates 5 of the inner-lying rows 8 rest. Advantageously, the damper element 12 or the damping mass 11 consists at least substantially of silicone.

In a final step according to FIG. 1D, the connecting webs 7 running in the parallel planes and the frame 4 are separated and the punched mesh 3 is thereby singulated. Only the connecting webs 7 forming the spring elements 10 are preserved. These later form the electrical connection 25 from an electrical/electronic structural part arranged on the upper side 13 to a substrate on which the coupling device 1 may be arranged by means of the underside 15.

The advantageous coupling device 1, as it is represented in FIG. 1D, offers both an electrical connection and a spring-mass system with a damper in a simple way.

The singulating of the punched mesh 3 is expediently performed by one or more punching operations. This preferably involves moving a punching tool substantially perpendicularly in relation to the upper side 13 or the underside 15, whereby a force is respectively applied in the direction of the damping mass to the connecting webs to be separated. Since the contact plates 5, and consequently the connecting webs to be separated, are respectively arranged outside the damping mass 11, the punching tool directly applies a force in the direction of the damping mass 11 to the connecting webs. The force and the rate of advancement of the punching tool are preferably chosen in this case in such a way that the damping mass is merely elastically deformed during the punching operation. As a result, the separated connecting webs can subsequently be removed particularly easily from the damping mass 11 or they detach themselves. It may possibly also be provided that the force and/or the rate of advancement are chosen in such a way that the connecting webs are driven into the damping mass 11 during the punching operation, so that the damping mass 11 is also plastically deformed. In the latter case, the detached connecting webs may subsequently remain in the damping mass 11. As a result, the damping property of the coupling device as a whole can be further changed or influenced. The electrical connections 25 lying in the damping mass 11 are intended to remain, and consequently also do not have to be taken into consideration in the punching operation.

Advantageously, a multiplicity of punched meshes 3 are provided, forming a punched mesh matrix, and preferably held by a common frame and separated from one another by a separate punching operation or during the punching operation described above, which serves for singulating the respective punched mesh 3, and are divided into individual punched meshes 3, as represented by way of example in FIG. 1D. Consequently, a multiplicity of the advantageous coupling devices 1 according to the exemplary embodiment of FIG. 1D can be produced in a simple way. It is particularly advantageous if production does not involve encapsulating a single punched mesh 3 with damping mass but instead simultaneously encapsulating the punched meshes of a punched mesh matrix (also known as a punched mesh array) with damping mass and subsequently singulating them.

In order to connect or attach an electrical/electronic structural part particularly easily to the coupling device 1, advantageously soldering paste is respectively applied to the contact areas 14. As a result, rapid mounting of a corresponding structural part on the coupling device is ensured.

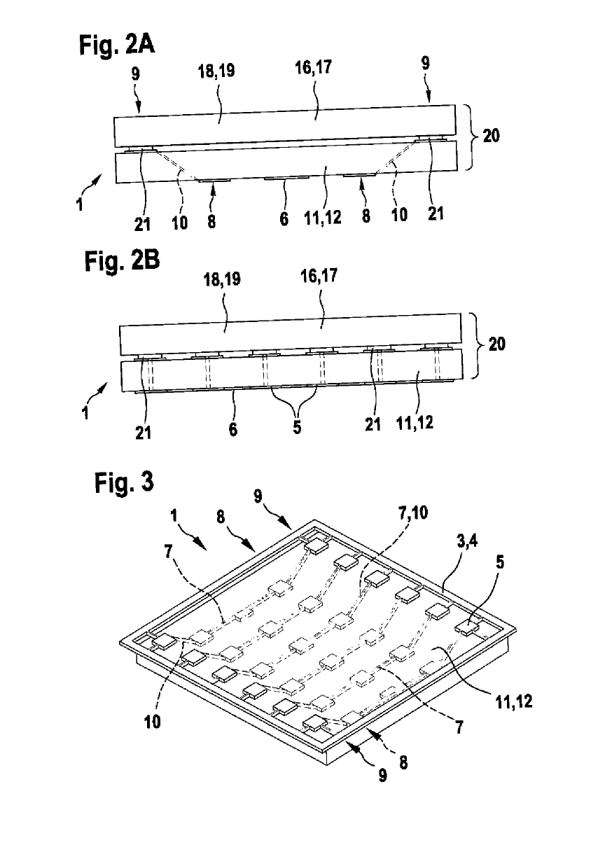

FIGS. 2A and 2B show the coupling device 1 in a side view in the direction of the longitudinal extent of the web 6 (FIG. 2A) and perpendicular thereto (FIG. 2B). An electrical/electronic structural part 16, which is formed as a sensor 17 with movement-sensitive micromechanics, has been applied here to the coupling device 1 known from FIG. 1D. All that is shown here of the sensor 17 is a housing 18, which is formed as a molded housing 19 and has on its side facing the coupling device 1 electrical contacts, which rest on the contact areas 14 of the coupling device 1. The housing 18 is advantageously adhesively attached to the damper element 12. The assembly 20 formed as a result, consisting of the coupling device 1 and the structural part 16, can then be soldered for example on a substrate, such as for example on a circuit board, wherein the connection between the coupling device 1 and the housing 18 is also established in the same step by soldering with the aid of the soldering paste 21. The advantageous connection of the structural part 16 to the circuit board by way of the coupling device 1 has the effect that the structural part 16 is decoupled in terms of vibration, so that the sensitive micromechanics of the sensor 17 are not influenced in an unwanted manner by vibrations. In addition, the functional capability is ensured to the extent that no stresses that could destroy the soldered connections occur between the sensor 17 and the circuit board, for example on account of tolerances during the mounting or due to temperature-induced material changes.

FIG. 3 shows a further embodiment of the coupling device 1 given by way of example, before the singulation of the punched mesh 3. As a difference from the exemplary embodiment known from FIG. 1C, the punched mesh 3 does not have a web 6. Provided instead are a number of rows of five contact plates each, which extend over the width of the punched mesh 3 and are connected to one another by way of connecting webs 7 only in the respective row. Of course, any number of different configurations of the punched mesh 3 are conceivable.

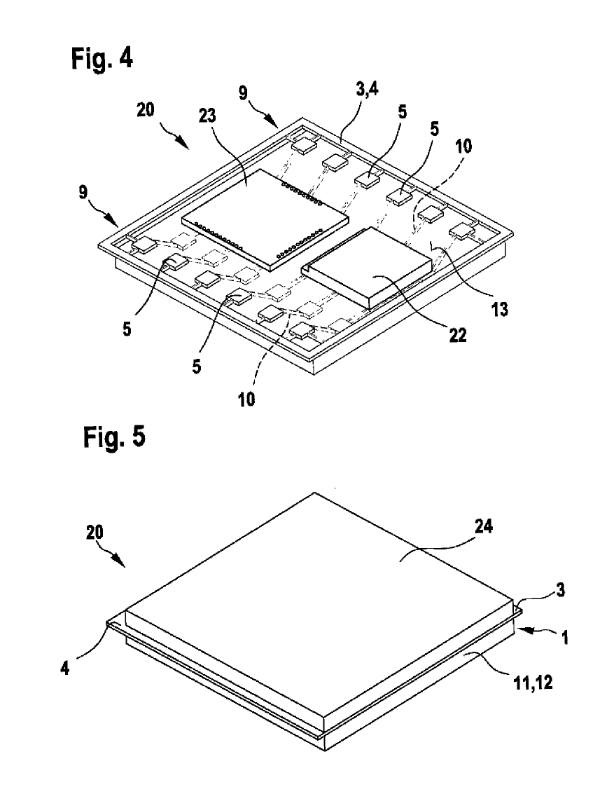

FIG. 4 shows an advantageous exemplary embodiment of a development of the assembly 20. According to this exemplary embodiment, the coupling device 1 forms an integral constituent part of the structural part 16 or of the sensor 17. For this purpose, in the present case two components 22, 23 of the sensor 17 are arranged on the damper element 12 (on the upper side 13) between the outer-lying rows 9 of the contact plates 5.

Subsequently, the components 22 and 23 are advantageously electrically contacted or connected to the contact areas 14 of the punched mesh 3 by means of bonded connections. In the step which then follows, the coupling device 1 and the components 22, 23 located thereupon and the contact plates 5 are housed by a molding process, whereby a molded housing 24 is formed. Subsequently, the desired connecting webs 7 are removed and the punched mesh 3 is singulated and the frame 4 removed. As a result, on the one hand the components 22, 23 and the bonded connections are protected from external influences, and on the other hand a particularly compact and easy-to-handle assembly 20 is offered.

The fact that the molded housing 24 is formed directly on the coupling device 1, by an injecting and/or molding operation, means that the coupling device 1 is integrated in the assembly 20. The assembly 20 configured in this way must then just be attached to a substrate—not represented here—, for example by means of soldering. In a further exemplary embodiment, not represented here, the circuit board or the substrate likewise forms a constituent part of the assembly 20, so that, by means of a circuit board, the assembly 20 can be produced and offered as a structural unit.

In principle, it is also conceivable to arrange the components 22, 23 on the underside 15 of the damper element 12, in particular on the copper web 6, in order to make the creation of the bonded connections easier.

1. A coupling device (1) for connecting an electrical/electronic structural part (16), having a substrate, wherein the coupling device (1) comprises at least one electrical connection (25) for the making of electrical contact and at least one damper element (12) for the decoupling of movement, characterized in that the electrical connection is formed by a punched mesh (3) and the punched mesh (3) is encapsulated at least in certain regions by a damping mass (11) as the damper element (12).

2. The coupling device as claimed in claim 1, characterized in that the punched mesh (3) forms at least in certain regions at least one spring element (10).

3. The coupling device as claimed in claim 1, characterized in that the punched mesh (3) has contact plates (5) that are exposed at least on one side.

4. The coupling device as claimed in claim 1, characterized in that the damping mass (11) is silicone.

5. An assembly having at least one electrical/electronic structural part (16), which can be arranged on a substrate, and having a coupling device (1) for connecting the structural part to the substrate, wherein the coupling device (1) comprises at least one electrical connection (25) for the making of electrical contact and at least one damper element (12) for the decoupling of movement, characterized by the coupling device (1) being formed by a punched mesh (3) and the punched mesh (3) is encapsulated at least in certain regions by a damping mass (11) as the damper element (12).

6. The assembly as claimed in claim 5, characterized in that the structural part (16) has a housing (18), with at least one electrical contact, which rests on a contact plate (5) of the punched mesh (3).

7. The assembly as claimed in claim 6, characterized in that the contact is soldered to the contact plate (5).

8. The assembly as claimed in claim 6, characterized in that at least one electrical/electronic component (22, 23) of the structural part (16) is arranged on the damper element (12).

9. The assembly as claimed in claim 8, characterized in that the component (22, 23) is electrically connected to the contact plate (5) by means of at least one bonded connection.

10. The assembly as claimed in claim 8, characterized in that the coupling device (1) is integrated at least in certain regions with the component (22, 23) and the contact plate (5) in a molded housing (24).

11. A method for producing an assembly, wherein the assembly comprises at least one electrical/electronic structural part, which can be arranged on a substrate, and a coupling device for connecting the structural part to the substrate, wherein the coupling device comprises at least one electrical connection for the making of electrical contact and at least one damper element for the decoupling of movement, the method comprising forming the connection by a punched mesh, and encapsulating the punched mesh in certain regions by a damping mass to form the damper element.

12. The method as claimed in claim 11, characterized in that a housing of the structural part is soldered to the punched mesh.

13. The method as claimed in claim 11, characterized in that at least one electrical/electronic component of the structural part is arranged on the damper element and is electrically connected to the punched mesh.

14. The method as claimed in claim 11, characterized in that the coupling device is housed at least in certain regions by means of a molding operation.
